(19) United States
(12) Patent Application Publication
(10) Pub. No.: US 2010/0123476 A1
(43) Pub. Date: May 20, 2010

(54) CONDUCTIVE CONTACT

(75) Inventors: Toshio Kazama, Nagano (JP); Shigeki Ishikawa, Nagano (JP)

Correspondence Address: EDWARDS ANGELL PALMER & DODGE LLP, P.O. BOX 55874, BOSTON, MA, 02205, US

(73) Assignee: NHK SPRING CO., LTD., KANAGAWA (JP)

(21) Appl. No.: 12/451,128

(22) PCT Filed: Apr. 25, 2008
(86) PCT No.: PCT/JP2008/058044

§ 371 Date: Oct. 27, 2009

(30) Foreign Application Priority Data
Apr. 27, 2007 (JP) 2007-119060

(51) Int. Cl. G01R 31/02

(52) U.S. Cl. 324/757

(57) ABSTRACT

A conductive contact includes a first plunger 11 which is formed approximately in a needle-shape and is formed of conductive material and of which tip portion has an axisymmetric shape; a second plunger 12 which is formed approximately in a needle-shaped and is formed of conductive material, of which tip portion 12a is oriented in a direction opposite to a tip portion 11a of the first plunger 11, and of which tip portion 12a has an axisymmetric shape with respect to an axis line same as that of the tip portion 11a of the first plunger 11; and a spring member 13 which is formed of conductive material, of which one end is in contact with the first plunger 11 and the other end is in contact with the second plunger 12, and which is extendable in a longitudinal direction, in which a base end portion 11d of the first plunger 11 and a base end portion 12d of the second plunger 12 are slidably in contact with each other.

### TECHNICAL FIELD

The present invention relates to a conductive contact that performs input and output of a signal in an electrical characteristics test on a semiconductor integrated circuit or the like.

### BACKGROUND ART

In an electrical characteristics test for a semiconductor integrated circuit such as an IC chip, a conductive contact unit is used that houses a plurality of conductive contacts at predetermined positions corresponding to an arrangement pattern of external connection electrodes included in the semiconductor integrated circuit. In such a conductive contact unit, both end portions of the conductive contact are brought into contact with a spherical electrode of the semiconductor integrated circuit and an electrode on a circuit substrate for the test, respectively, to establish an electrical connection at the test (see Patent Document 1, for example).

Patent Document 1: Japanese Patent Application Laid-open No. 2002-107377

### DISCLOSURE OF INVENTION

### Problem to be Solved by the Invention

In recent years, a demand is growing for a semiconductor capable of coping with a high frequency of 1 GHz or more. For performing the electrical characteristics test on such a semiconductor, the inductance or the resistance of the conductive contact needs to be lowered. In view of this, it is preferable that the diameter of the conductive contact is made large and the length of the conductive contact is shortened. Although machining the conductive contact having a large diameter is relatively easy, machining the conductive contact, of which entire length is made short, is difficult. In the case of the conductive contact having a configuration in which two plungers positioned at both ends are coupled with a spring member, for example, the pitch of the winding of the spring member is sometimes changed in the middle and two plungers are brought into contact with each other at a tightly wound portion in order to ensure desired spring characteristics and realize an effective conductive path. In order to shorten the entire length of the conductive contact, the distance between the two plungers needs to be shortened by shortening the tightly wound portion of the spring member, so that the stroke required for the conductive contact may not be ensured.

The present invention has been made in view of the above, and it is an object of the present invention to provide a conductive contact that is capable of performing transmission and reception of a signal with high frequency of 1 GHz of more and can be machined easily.

### Means for Solving Problem

To solve the problem described above and achieve the object, a conductive contact according to the present invention includes a first plunger which is formed approximately in a needle-shape and is formed of conductive material and of which tip portion has an axisymmetric shape; a second plunger which is formed approximately in a needle-shape and is formed of conductive material, of which tip portion is oriented in a direction opposite to the tip portion of the first plunger, and of which tip portion has an axisymmetric shape with respect to an axis line same as that of the tip portion of the first plunger; and a spring member which is formed of conductive material, of which one end is in contact with the first plunger and another end is in contact with the second plunger, and which is extendable in a longitudinal direction, wherein a base end portion of the first plunger and a base end portion of the second plunger are slidably in contact with each other.

In the conductive contact according to the present invention as set forth in the invention described above, the base end portion of the first plunger and the base end portion of the second plunger have same cross sectional shape.

In the conductive contact according to the present invention as set forth in the invention described above, the base end portion of the first plunger and the base end portion of the second plunger have a shape engagable with each other.

In the conductive contact according to the present invention as set forth in the invention described above, the first plunger and the second plunger have same shape.

In the conductive contact according to the present invention as set forth in the invention described above, the spring member is such that a pitch of a winding is same except for end portions at which the first plunger and the second plunger are attached.

In the conductive contact according to the present invention as set forth in the invention described above, the spring member is such that a pitch of a winding changes along the longitudinal direction and a portion positioned near an outer periphery of a position at which the base end portion of the first plunger and the base end portion of the second plunger are in contact with each other in a state where the spring member is not stroked is tightly wound.

In the conductive contact according to the present invention as set forth in the invention described above, the spring member is such that a diameter of a winding changes along the longitudinal direction and the diameter of the winding is maximum at a portion positioned near an outer periphery of a position at which the base end portion of the first plunger and the base end portion of the second plunger are in contact with each other in a state where the spring member is not stroked.

### EFFECT OF THE INVENTION

According to the present invention, it is possible to provide a conductive contact which includes the first plunger which is formed approximately in a needle-shape and is formed of conductive material and of which tip portion has an axisymmetric shape, the second plunger which is formed approximately in a needle-shape and is formed of conductive material, of which tip portion is oriented in a direction opposite to the tip portion of the first plunger, and of which tip portion has an axisymmetric shape with respect to the axis line same as that of the tip portion of the first plunger, and a spring member which is formed of conductive material, of which one end is in contact with the first plunger and the other end is in contact with the second plunger, and which is extendable in the longitudinal direction. The conductive contact is capable of transmitting and receiving a signal with high frequency of 1 GHz or more by bringing the base end portion of the first plunger into slidably contact with the base end portion of the second plunger. The conductive contact can be easily machined.

### BRIEF DESCRIPTION OF DRAWINGS

FIG. 1 is a diagram illustrating a configuration of a conductive contact according to a first embodiment of the present invention.

FIG. 2 is a diagram illustrating a contact form of a base end portion of a first plunger and a base end portion of a second plunger.

FIG. 3 is a diagram illustrating a configuration of a relevant portion of a conductive contact holder that houses the conductive contact according to the first embodiment of the present invention.

FIG. 4 is a diagram explaining an effect caused by the conductive contact according to the first embodiment of the present invention.

FIG. 5 is a diagram illustrating a configuration of a conductive contact according to a first modified example of the first embodiment of the present invention.

FIG. 6 is a diagram illustrating a contact form of a base end portion of a first plunger and a base end portion of a second plunger of a conductive contact according to a second modified example of the first embodiment of the present invention.

FIG. 7 is a diagram illustrating a contact form of a base end portion of a first plunger and a base end portion of a second plunger of a conductive contact according to a third modified example of the first embodiment of the present invention.

FIG. 8 is a diagram illustrating a configuration of a conductive contact according to a second embodiment of the present invention.

FIG. 9 is a diagram illustrating a configuration of a conductive contact according to a modified example of the second embodiment of the present invention.

FIG. 10 is a diagram illustrating a configuration of a conductive contact according to another embodiment of the present invention.

FIG. 11 is a diagram illustrating a configuration of a conductive contact according to still another embodiment of the present invention.

### EXPLANATIONS OF LETTERS OR NUMERALS

1, 3, 4, 5, 6, 7, 8 conductive contact conductive contact holder
11, 31, 51, 61 first plunger
12, 32, 52, 62 second plunger
11a, 12a, 31a, 32a, 51a, 52a, 61a, 62a tip portion
11b, 12b, 31b, 32b, 51b, 52b, 61b, 62b flange portion
11c, 12c, 31c, 32c, 51c, 52c, 61c, 62c boss portion
11d, 11-2d, 11-3d, 12d, 12-2d, 12-3d, 31d, 32d, 51d, 52d, 61d, 62d base end portion
13, 33, 71, 81 spring member
21 first substrate
22 second substrate
33a, 81a, 81b loosely wound portion
33b, 81c tightly wound portion
100 circuit substrate
101, 201 electrode
200 test object
211, 221 hole portion
211a, 221a small diameter hole
211b, 221b large diameter hole

### BEST MODE(S) FOR CARRYING OUT THE INVENTION

Preferred embodiments (hereinafter, “embodiments”) of the present invention will be described below with reference to the accompanying drawings. It should be noted that the drawings are schematic and a relation between the thickness and the width of each portion, a ratio of the thicknesses of the respective portions, and the like may be different from realistic ones. It goes without saying that the drawings may depict some portion as having different relations and ratios of dimensions.

### First Embodiment

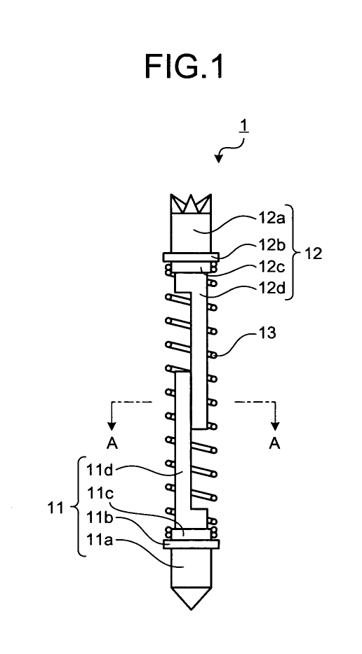

FIG. 1 is a diagram illustrating a configuration of a conductive contact according to a first embodiment of the present invention. A conductive contact 1 shown in FIG. 1 is formed of conductive material, and includes a first plunger 11 having a sharp tip end, a second plunger 12 having a crown-shaped tip that projects in a direction opposite to the first plunger 11, and a spring member 13 that is in contact with the first plunger 11 at one end and with the second plunger 12 at the other end and is extensible in a longitudinal direction.

The first plunger 11 includes a tip portion 11a having the sharp tip end, a flange portion 11b having a diameter larger than the diameter of the tip portion 11a, a boss portion 11c which projects in an opposite direction of the tip portion 11a via the flange portion lib, which has a cylindrical shape with a diameter that is smaller than the diameter of the flange portion 11b and is slightly larger than the inner diameter of the spring member 13, and onto which the end portion of the spring member 13 is press fitted, and a base end portion 11d that extends on the opposite side of the flange portion 11b from the boss portion 11c. The tip portion 11a, the flange portion 11b, and the boss portion 11c have an axisymmetric shape with respect to the central axis parallel to the longitudinal direction. The base end portion 11d has a shape that is formed by cutting out a part from a cylinder having a diameter smaller than the diameter of the boss portion 11c and the inner diameter of the spring member 13. The cut-out part includes an end portion of the base end portion 11d on a side that is not in contact with the boss portion 11c. The cut-out part is cut along the longitudinal direction and has a semi-cylindrical shape.

The second plunger 12 includes a tip portion 12a having a crown shape, a flange portion 12b having a diameter larger than the diameter of the tip portion 12a, a boss portion 12c which projects in an opposite direction of the tip portion 12a via the flange portion 12b, which has a cylindrical shape with a diameter that is smaller than the diameter of the flange portion 12b and is slightly larger than the inner diameter of the spring member 13, and onto which the end portion of the spring member 13 is press fitted, and a base end portion 12d that extends on the opposite side of the flange portion 12b from the boss portion 12c. The tip portion 12a, the flange portion 12b, and the boss portion 12c have an axisymmetric shape with respect to the central axis parallel to the longitudinal direction. The base end portion 12d has a shape same as the base end portion 11d of the first plunger 11.

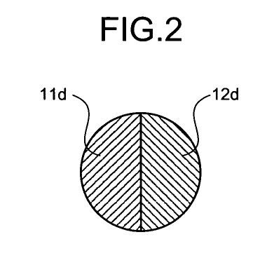

The base end portion 11d of the first plunger 11 and the base end portion 12d of the second plunger 12 are slidably in contact with each other near each end portion thereof. FIG. 2 is a diagram illustrating a contact form of the base end portions 11d and 12d and is a diagram corresponding to a cross section taken along line A-A in FIG. 1. The cross sections of parts of the base end portions 11d and 12d that are in contact with each other have the same semi-circular shape, and the side surfaces that pass the center of each semicircle and extend in the longitudinal direction are in contact with each other. The first plunger 11 and the second plunger 12 are slidably in contact with each other as described above, so that a conductive path directly reaching the base end portion 12d from the base end portion 11d can be ensured.

The first plunger 11 and the second plunger 12 are formed, for example, by lathe machining. This is applicable to the following embodiments and the others. The length of the base end portion 11d of the first plunger 11 and the length of the base end portion 12d of the second plunger 12 can be appropriately changed and can be different from each other.

The spring member 13 is a coil spring having a uniform diameter, and both end portions thereof are press fitted onto the boss portion 11c of the first plunger 11 and the boss portion 12c of the second plunger 12, respectively. The pitch of the winding of the spring member 13 is uniform except for the both end portions that are press fitted onto the first plunger 11 and the second plunger 12. The axis line of the spring member 13 coincides with the axis line of part of the first plunger 11 excluding the base end portion 11d and the axis line of part of the second plunger 12 excluding the base end portion 12d.

In the conductive contact 1 having the above configuration, the parts of the base end portion 11d and the base end portion 12d that are in contact with each other do not separate even when a load is applied to the conductive contact 1 and the spring member 13 is stroked while meandering. Consequently, reliable slide friction can be ensured.

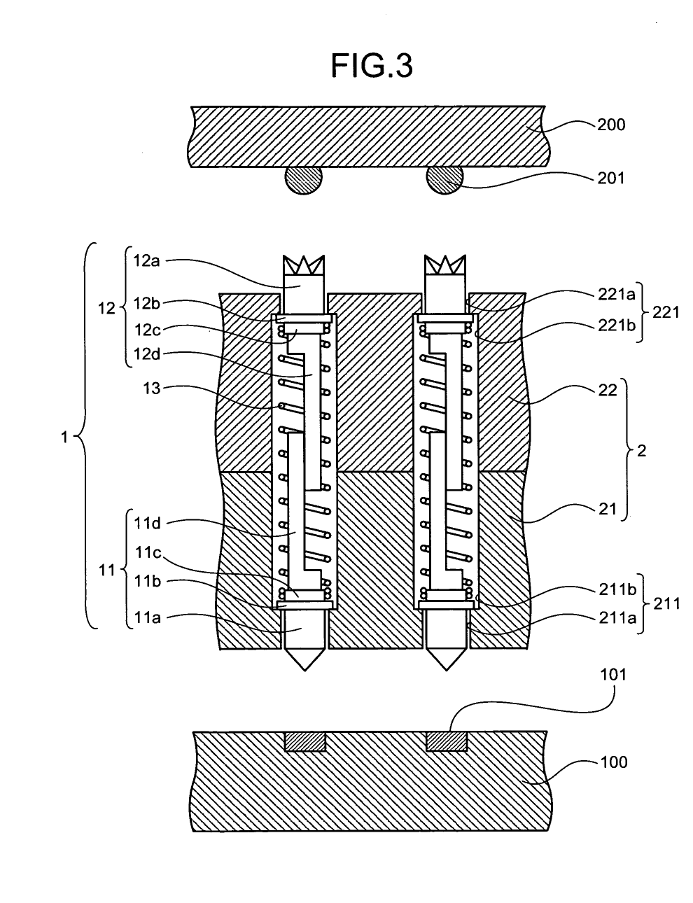

FIG. 3 is a diagram illustrating a configuration of a relevant portion of a conductive contact holder that houses the conductive contacts 1 and a configuration of contact target bodies that are in contact with the both end portions of the conductive contacts 1. A conductive contact holder 2 shown in FIG. 3 is formed by stacking a first substrate 21 and a second substrate 22 in a plate thickness direction. In the first substrate 21, hole portions 211 in which a plurality of the conductive contacts 1 is individually housed are formed. The hole portion 211 has a stepped-hole shape that includes a small diameter portion 211a having a diameter slightly larger than the diameter of the tip portion 11a of the first plunger 11 and a large diameter portion 211b having a diameter slightly larger than the diameter of the flange portion 11b.

In the second substrate 22, hole portions 221 in which a plurality of the conductive contacts 1 is individually housed are formed. The hole portion 221 has a stepped-hole shape that includes a small diameter portion 221a having a diameter slightly larger than the diameter of the tip portion 12a of the second plunger 12 and a large diameter portion 221b having a diameter slightly larger than the diameter of the flange portion 12b. The diameter of the large diameter portion 221b is equal to the diameter of the large diameter portion 211b.

When the conductive contacts 1 are housed and the first substrate 21 and the second substrate 22 are stacked, the hole portion 211 and the hole portion 221 that correspond to each other communicate in the axis direction.

The tip portion 11a of the first plunger 11 of the conductive contact 1 that the conductive contact holder 2 houses is in contact with an electrode 101 provided on a circuit substrate 100 that outputs a signal for a test. In contrast, the tip portion 12a of the second plunger 12 of the conductive contact 1 that the conductive contact holder 2 houses is in contact with an electrode 201 of a test object 200 such as a semiconductor integrated circuit. In the case shown in FIG. 3, the surface of the electrode 101 is flat, whereas the surface of the electrode 201 is spherical. The tip portion 11a of the first plunger 11 forms a sharp tip end, whereas the tip portion 12a of the second plunger 12 forms a crown shape, to ensure a suitable contact state in accordance with the shape of the electrodes 101 and 201. In this manner, the shape of the tip portion of each plunger can be defined in accordance with the shape of the electrode that is in contact therewith.

The first substrate 21 and the second substrate 22 that construct the conductive contact holder 2 are formed by using insulating material such as resin, machinable ceramic, and silicone. The hole portion 211 and the hole portion 221 formed in the first substrate 21 and the second substrate 22, respectively, are formed by performing drilling, etching, or punching, or performing a process using a laser, an electron beam, an ion beam, a wire electrical discharge, or the like.

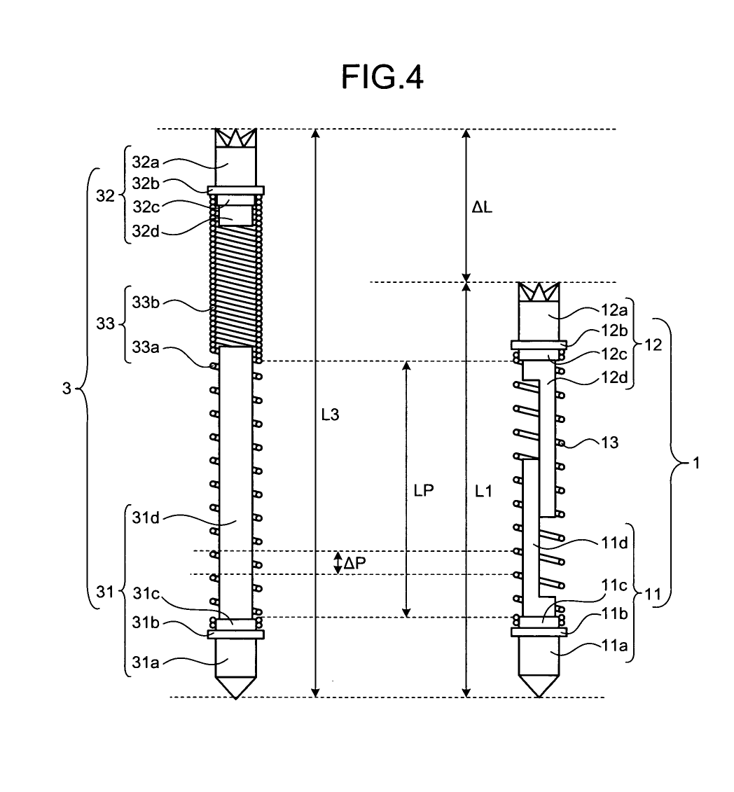

FIG. 4 is a diagram explaining an effect of the conductive contact 1 according to the first embodiment of the present invention. A conductive contact 3 shown in FIG. 4 is a conventional conductive contact. The conductive contact 3 includes a first plunger 31 having a sharp tip end, a second plunger 32 having a crown-shaped tip that projects in a direction opposite to the first plunger 31, and a spring member 33 that couples the first plunger 31 and the second plunger 32.

The first plunger 31 includes a tip portion 31a, a flange portion 31b having a diameter larger than the diameter of the tip portion 31a, a boss portion 31c which projects in an opposite direction of the tip portion 31a via the flange portion 31b, which has a cylindrical shape with a diameter that is smaller than the diameter of the flange portion 31b and is slightly larger than the inner diameter of the spring member 33, and onto which the end portion of the spring member 33 is press fitted, and a base end portion 31d that has a cylindrical shape with a diameter that is smaller than the diameter of the boss portion 31c and is smaller than the inner diameter of the spring member 33. The second plunger 32 includes a tip portion 32a having a crown shape, a flange portion 32b having a diameter larger than the diameter of the tip portion 32a, a boss portion 32c which projects in an opposite direction of the tip portion 32a via the flange portion 32b, which has a cylindrical shape with a diameter that is smaller than the diameter of the flange portion 32b and is slightly larger than the inner diameter of the spring member 33, and onto which the end portion of the spring member 33 is press fitted, and a base end portion 32d that has a cylindrical shape with a diameter that is smaller than the diameter of the boss portion 32c and is smaller than the inner diameter of the spring member 33. The first plunger 31 side of the spring member 33 is a loosely wound portion 33a, while the second plunger 32 side thereof is a tightly wound portion 33b. The end portion of the loosely wound portion 33a is press fitted onto the boss portion 31c of the first plunger 31, while the end portion of the tightly wound portion 33b is press fitted onto the boss portion 32c of the second plunger 32. The conductive contact 3 is configured so that the base end portion 31d is in contact with the tightly wound portion 33b, and the shortest conductive path in an order of the first plunger 31, the tightly wound portion 33b, and the second plunger 32 is formed.

Contrary to the conductive contact 3 having the above configuration, in the conductive contact 1 according to the first embodiment, the base end portion 11d of the first plunger 11 and the base end portion 12d of the second plunger 12 are slidably in contact with each other, so that the conductive path directly reaching the base end portion 12d from the base end portion 11d without via the spring member 13 can be ensured. Thus, there is no need to provide a tightly wound portion in the spring member.

In the case shown in FIG. 4, in order to cause the conductive contact 1 and the conductive contact 3 to have the same spring characteristics, the length of the loosely wound portion 33a and the length of the spring member 13 are made equal to LP, and the pitch of the winding of the loosely wound portion 33a and the pitch of the winding of the spring member 13 are made equal to ΔP. In this case, in the conductive contact 1, the tightly-wound portion does not need to be provided as described above, so that the entire length L1 thereof can be made shorter than the entire length L3 of the conductive contact 3 (L1-L3=ΔL). Consequently, the inductance or the resistance of the conductive contact can be reduced compared with the conventional type, enabling to realize excellent high frequency characteristics.

According to the first embodiment of the present invention described above, it is possible to provide the conductive contact which includes the first plunger which is formed approximately in a needle-shape and is formed of conductive material and of which tip portion has an axisymmetric shape, the second plunger which is formed approximately in a needle-shape and is formed of conductive material, of which tip portion is oriented in a direction opposite to the tip portion of the first plunger, and of which tip portion has an axisymmetric shape with respect to the axis line same as that of the tip portion of the first plunger, and a spring member which is formed of conductive material, of which one end is in contact with the first plunger and the other end is in contact with the second plunger, and which is extendable in the longitudinal direction. The conductive contact is capable of transmitting and receiving a signal with high frequency of 1 GHz or more by bringing the base end portion of the first plunger into slidably contact with the base end portion of the second plunger, and the conductive contact can be easily machined.

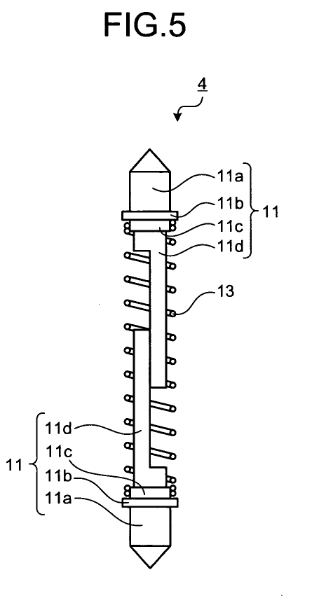

As a first modified example of the first embodiment, as shown in FIG. 5, it is possible to configure a conductive contact 4 in which the second plunger has the same shape as the first plunger. In this case, the base end portions 11d of the respective plungers are slidably in contact with each other as a matter of course.

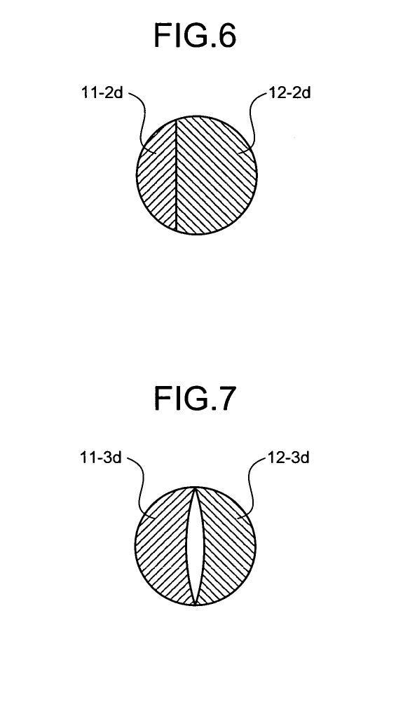

Moreover, as a second modified example of the first embodiment, it is possible to form cross sections (the cross section corresponding to FIG. 2) of the contact portions of the base end portions of the two plungers that are vertical to the longitudinal direction into an asymmetrical shape. For example, as shown in FIG. 6, a cross-section area of a base end portion 11-2d of the first plunger can be made smaller than a cross-section area of a base end portion 12-2d of the second plunger, and the cross section combining the two base end portions 11-2d and 12-2d can have a circular shape.

Furthermore, as a third modified example of the first embodiment, as shown in FIG. 7, it is possible to configure such that a cross section of a contact portion of a base end portion 11-3d of the first plunger and a base end portion 12-3d of the second plunger has a clearance.

### Second Embodiment

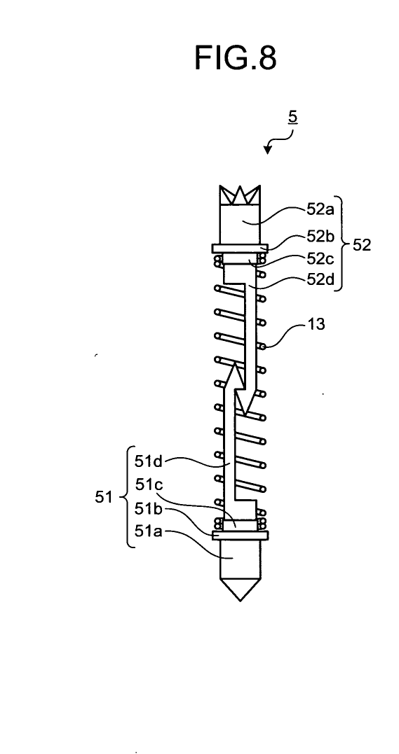

FIG. 8 is a diagram illustrating a configuration of a conductive contact according to the second embodiment of the present invention. A conductive contact 5 shown in FIG. 8 includes a first plunger 51, a second plunger 52, and the spring member 13 that is in contact with the first plunger 51 at one end and with the second plunger 52 at the other end and is extensible in the longitudinal direction.

The first plunger 51 includes a tip portion 51a having a sharp tip end, a flange portion 51b having a diameter larger than the diameter of the tip portion 51a, a boss portion 51c that projects in an opposite direction of the tip portion 51a via the flange portion 51b, has a cylindrical shape with a diameter that is smaller than the diameter of the flange portion 51b and is slightly smaller than the inner diameter of the spring member 13, and suppresses the movement of the end portion of the spring member 13 in a radial direction, and a base end portion 51d that extends on the opposite side of the flange portion 51b from the boss portion 51c. The base end portion 51d is configured such that the end portion on the side that is in contact with the boss portion 51c has a cylindrical shape with a diameter smaller than the diameter of the boss portion 51c and the inner diameter of the spring member 13 and the end portion on the side that is not in contact with the boss portion 51c has a hook shape. The middle portion of the base end portion 51d has a shape that is formed by cutting out part of a cylinder along the longitudinal direction. The cylinder is formed by the end portion on a side that is in contact with the boss portion 51c.

The second plunger 52 includes a tip portion 52a having a crown shape, a flange portion 52b having a diameter larger than the diameter of the tip portion 52a, a boss portion 52c that projects in an opposite direction of the tip portion 52a via the flange portion 52b, has a cylindrical shape with a diameter that is smaller than the diameter of the flange portion 52b and is slightly smaller than the inner diameter of the spring member 13, and suppresses the movement of the end portion of the spring member 13 in the radial direction, and a base end portion 52d that extends on the opposite side of the flange portion 52b from the boss portion 52c. The base end portion 52d has the same shape as the base end portion 51d of the first plunger 51, and the end portion of the base end portion 52d having a hook shape can be engaged with the end portion of the base end portion 51d having a hook shape.

The base end portion 51d of the first plunger 51 and the base end portion 52d of the second plunger 52 are configured to be engagable with each other, so that an initial load can be applied in a state where the conductive contact 5 is assembled. Therefore, the both end portions of the spring member 13 do not need to be pressed and fixed to the first plunger 51 and the second plunger 52, so that the assembling work of a probe can be made easier. Moreover, regarding the hole portion in the conductive contact holder, there is no need to form both ends thereof into a stepped-hole shape and apply an initial load, so that warping of the conductive contact holder due to the load can be eliminated. Furthermore, if only the lower end of the hole portion is formed into a stepped-hole shape to prevent the conductive contact 5 from coming off, the conductive contact holder can be formed from one substrate, thus enabling to reduce the number of components and man-hours and realize a low cost. Moreover, when the conductive contact 5 is inserted into the conductive contact holder having the similar configuration to that shown in FIG. 3 and two substrates are combined, a load of the conductive contact 5 is not applied to each substrate, so that assembling becomes easy.

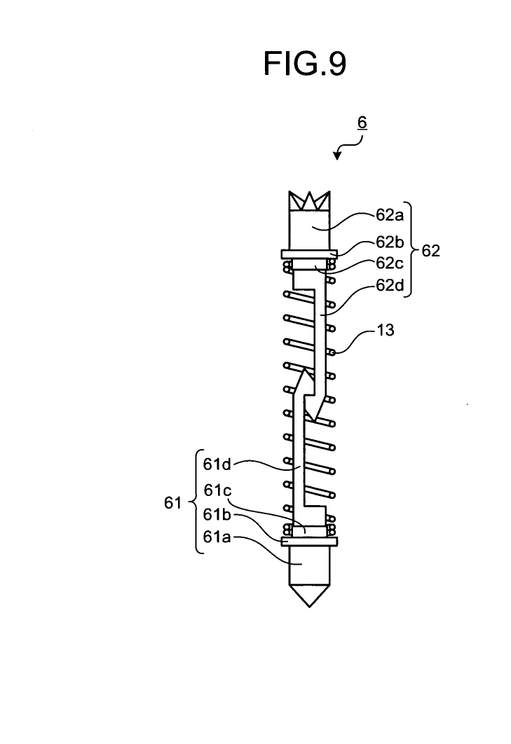

The shape of the base end portions 51d and 52d shown in FIG. 8 is just an example. For example, as a conductive contact 6 shown in FIG. 9, the shape can be such that a base end portion 61d of a first plunger 61 and a base end portion 62d of a second plunger 62 are engaged with each other and are slidably in contact with each other in the longitudinal direction. In the conductive contact 6, a tip portion 61a, a flange portion 61b, and a boss portion 61c of the first plunger 61 have the similar shape to the tip portion 51a, the flange portion 51b, and the boss portion 51c of the first plunger 51 of the conductive contact 5, respectively. A tip portion 62a, a flange portion 62b, and a boss portion 62c of the second plunger 62 have the similar shape to the tip portion 52a, the flange portion 52b, and the boss portion 52c of the second plunger 52 of the conductive contact 5, respectively.

According to the second embodiment of the present invention described above, it is possible to provide the conductive contact which includes the first plunger which is formed approximately in a needle-shape and is formed of conductive material and of which tip portion has an axisymmetric shape, the second plunger which is formed approximately in a needle-shape and is formed of conductive material, of which tip portion is oriented in a direction opposite to the tip portion of the first plunger, and of which tip portion has an axisymmetric shape with respect to the axis line same as that of the tip portion of the first plunger, and a spring member which is formed of conductive material, of which one end is in contact with the first plunger and the other end is in contact with the second plunger, and which is extendable in the longitudinal direction. The conductive contact is capable of transmitting and receiving a signal with high frequency of 1 GHz or more by bringing the base end portion of the first plunger into slidably contact with the base end portion of the second plunger, and the conductive contact can be easily machined.

Moreover, according to the second embodiment, the base end portion of the first plunger and the base end portion of the second plunger have a shape engagable with each other, so that an initial load can be applied to the conductive contact by the engagement. Consequently, the both end portions of the spring member do not need to be pressed and fixed to the first plunger and the second plunger, respectively, so that manufacturing of the conductive contact becomes easy. Moreover, the conductive contact holder can be formed from one substrate, and thus the configuration of the hole portion in which the conductive contact is housed can be made simple, enabling to make manufacturing easy. Consequently, the manufacturing cost for the conductive contact and the conductive contact holder can be reduced.

Furthermore, according to the second embodiment, because the conductive contact holder needs not apply a load on the conductive contact, warping of the conductive contact holder due to a reaction force of the spring member does not occur, so that the movement of the conductive contact can be made smooth and the positional accuracy of the tip of the conductive contact can be improved. In addition, assembling of the conductive contact holder in which the conductive contact is housed becomes easy.

In the second embodiment, the configuration can be such that the diameter of the boss portion of each plunger is made slightly larger than the inner diameter of the spring member and the end portions of the spring member are press fitted onto the boss portions in the similar manner to the above first embodiment.

### Other Embodiments

The first and second embodiments are described in detail as preferred embodiments of the present invention; however, the present invention should not be limited to these two embodiments. For example, as described below, regarding the spring member, the shape thereof can be changed in accordance with various conditions such as the material of the first plunger and the second plunger, the contact area of the base end portions of both plungers, and the entire length of the contact portion.

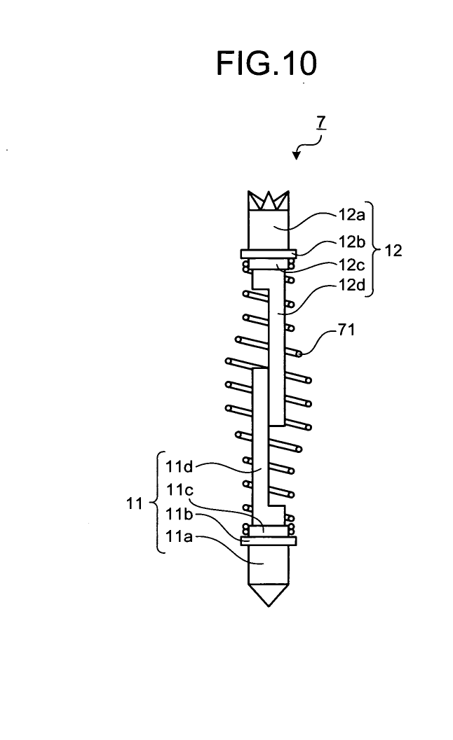

FIG. 10 is a diagram illustrating a configuration of a conductive contact according to another embodiment of the present invention. A conductive contact 7 shown in FIG. 10 includes the first plunger 11, the second plunger 12, and a spring member 71 that couples the first plunger 11 and the second plunger 12. The spring member 71 changes its diameter of the winding along the longitudinal direction, and has the maximum diameter of the winding at a portion positioned near the outer periphery of the position at which the base end portion 11d of the first plunger 11 and the base end portion 12d of the second plunger 12 are in contact with each other in a state where the spring member 71 is not stroked (a state shown in FIG. 10). Both end portions of the spring member 71 are press fitted onto the first plunger 11 and the second plunger 12, respectively.

According to the conductive contact 7 having the above configuration, smooth sliding between the base end portions 11d and 12d can be realized at the time of contact with a test object.

In the case shown in FIG. 10, because the diameter of the winding of the spring member 71 is smaller at the end portion in the longitudinal direction than at the center portion in the longitudinal direction, the contact pressure at the sliding portion between the base end portions 11d and 12d increases as the stroke of each plunger increases. However, because a load increases as the stroke increase, the stroke is not affected.

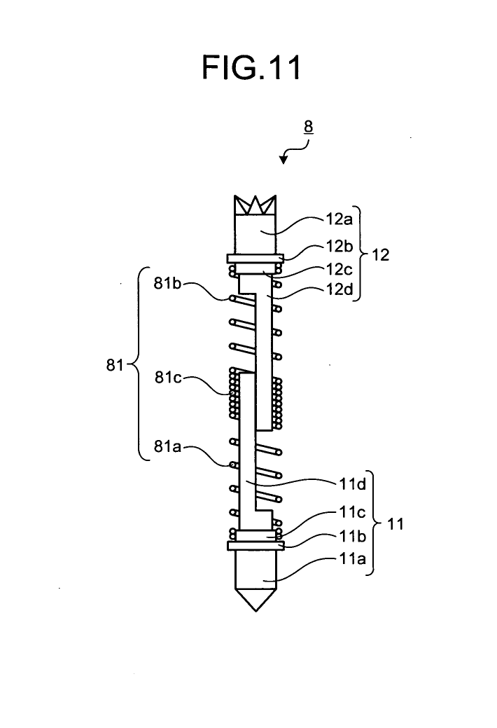

FIG. 11 is a diagram illustrating a configuration of a conductive contact according to still another embodiment of the present invention. A conductive contact 8 shown in FIG. 11 includes the first plunger 11, the second plunger 12, and a spring member 81 that couples the first plunger 11 and the second plunger 12. The spring member 81 changes its pitch of the winding along the longitudinal direction. Specifically, the first plunger 11 side of the spring member 81 is a loosely wound portion 81a and the second plunger 12 side thereof is a loosely wound portion 81b, and a tightly wound portion 81c that is tightly wound is provided between the loosely wound portion 81a and the loosely wound portion 81b. The tightly wound portion 81c is positioned near the outer periphery of the position at which the base end portion 11d of the first plunger 11 and the base end portion 12d of the second plunger 12 are in contact with each other in a state where the spring member 81 is not stroked. Both ends of the spring member 81 are press fitted onto the first plunger 11 and the second plunger 12, respectively.

According to the conductive contact 8 having the above configuration, contact between the base end portions 11d and 12d can be ensured.

The spring member described above can be applied regardless of the shape of the base end portion of each plunger. Accordingly, the spring member 71 or 81 can be applied instead of the spring member 13 of the above described conductive contacts 4 to 6.

As described above, the present invention can include various embodiments and the like not described here, and various design changes and the like can be made in the range without departing from the technical idea as specified by the claims.

### INDUSTRIAL APPLICABILITY

As described above, the conductive contact according to the present invention is useful when performing an electrical characteristics test on such as a semiconductor integrated circuit, and is particularly suitable for performing transmission and reception of a signal with high frequency of 1 GHz or more.

1. A conductive contact comprising:
a first plunger which is formed approximately in a needle-shape and is formed of conductive material and of which tip portion has an axisymmetric shape;
a second plunger which is formed approximately in a needle-shape and is formed of conductive material, of which tip portion is oriented in a direction opposite to the tip portion of the first plunger, and of which tip portion has an axisymmetric shape with respect to an axis line same as that of the tip portion of the first plunger; and
a spring member which is formed of conductive material, of which one end is in contact with the first plunger and another end is in contact with the second plunger, and which is extendable in a longitudinal direction, wherein
a base end portion of the first plunger and a base end portion of the second plunger are slidably in contact with each other.

2. The conductive contact according to claim 1, wherein the base end portion of the first plunger and the base end portion of the second plunger have a shape engagable with each other.

3. The conductive contact according to claim 1, wherein the base end portion of the first plunger and the base end portion of the second plunger have same cross sectional shape.

4. The conductive contact according to claim 3, wherein the base end portion of the first plunger and the base end portion of the second plunger have a shape engagable with each other.

5. The conductive contact according to claim 1, wherein the first plunger and the second plunger have same shape.

6. The conductive contact according to claim 1, wherein the spring member is such that a pitch of a winding is same except for end portions at which the first plunger and the second plunger are attached.

7. The conductive contact according to claim 1, wherein the spring member is such that a pitch of a winding changes along the longitudinal direction and a portion positioned near an outer periphery of a position at which the base end portion of the first plunger and the base end portion of the second plunger are in contact with each other in a state where the spring member is not stroked is tightly wound.

8. The conductive contact according to claim 1, wherein the spring member is such that a diameter of a winding changes along the longitudinal direction and the diameter of the winding is maximum at a portion positioned near an outer periphery of a position at which the base end portion of the first plunger and the base end portion of the second plunger are in contact with each other in a state where the spring member is not stroked.
